(19) United States
(12) Patent Application Publication
(10) Pub. No.: US 2021/0140031 A1
(43) Pub. Date: May 13, 2021

(54) OPEN MASK, OPEN MASK ASSEMBLY, AND EVAPORATION METHOD USING THE OPEN MASK

(71) Applicants: CHENGDU BOE OPTOELECTRONICS TECHNOLOGY CO., LTD., Chengdu (CN); BOE TECHNOLOGY GROUP CO., LTD., Beijing (CN)

(72) Inventor: Peng Xu, Beijing (CN)

(21) Appl. No.: 16/640,333

(22) PCT Filed: Aug. 29, 2019
(86) PCT No.: PCT/CN2019/103309

§ 371 Date: Feb. 19, 2020

(30) Foreign Application Priority Data
Oct. 15, 2018 (CN) 201811197777.6

(51) Int. Cl. C23C 14/04; C23C 14/24; C23C 14/12; H01L 51/00

(52) U.S. Cl. CPC C23C 14/042; H01L 51/0011; C23C 14/12; C23C 14/24

(57) ABSTRACT

According to an embodiment of the present disclosure, there is provided an open mask including: a plurality of unit elements arranged in an array, each unit element including an open area and a non-open area, the non-open area including a half-etched portion and a material reserved portion, wherein: in at least one unit element of the plurality of unit elements, the material reserved portion is located around the open area of the unit element, and the half-etched portion is isolated from the open area by the material reserved portion. An open mask assembly and an evaporation method using the open mask are further provided.

### CROSS-REFERENCE TO RELATED APPLICATION(S)

This application is the national phase of PCT Application No. PCT/CN2019/103309 filed on Aug. 29, 2019, which in turn claims priority to Chinese Patent Application No. 201811197777.6 filed on Oct. 15, 2018 in the State Intellectual Property Office of China, the disclosure of which is hereby incorporated by reference in its entirety.

### TECHNICAL FIELD

The present disclosure generally relates to the field of display technology, and particularly, to an open mask, an open mask assembly, and an evaporation method using the open mask.

### BACKGROUND

In the open mask (Open mask) design of the OLED display panel, when an open mask is used in evaporation to obtain a film layer, internal and external shadow (Shadow) effects need to be considered. The external shadow effect will cause the film layer to overlap or interfere, which may affect the packaging effect and other edge defects. In particular, for the shadow of a metal material that extends outside to the packaging area of the OLED, the metal compound film layer and the inorganic film layer used in the package have a small adhesion, which can cause peeling of the film layer, resulting in package failure and lower product reliability. Generally speaking, when the external shadow of a metal compound film layer (such as LiF) extends to the packaging area, Newton rings and other phenomena will appear in the appearance inspection. In this case, a gap has appeared between the metal compound film layer and the packaging film layer. When this happens during reliability testing, it is easy to cause package failure, thereby affecting the normal operation of the OLED device therein.

Therefore, it is an urgent problem to ease the external shadow effect of the open mask.

### SUMMARY

According to an aspect of the present disclosure, there is provided an open mask comprising:

a plurality of unit elements arranged in an array, each unit element comprising an open area and a non-open area, the non-open area comprising a half-etched portion and a material reserved portion, wherein:

in at least one unit element of the plurality of unit elements, the material reserved portion is located around the open area of the at least one unit element, and the half-etched portion is isolated from the open area by the material reserved portion.

In some embodiments, each unit element and its adjacent unit element have their half-etched portions adjoining each other.

In some embodiments, a thickness of the material reserved portion is approximately 145-155μm.

In some embodiments, a difference between the thickness of the material reserved portion and a thickness of the half-etched portion is at least approximately 10μm.

In some embodiments, a thickness of the half-etched portion is approximately 70-80μm.

In some embodiments, a width of the material reserved portion is greater than or equal to approximately 0.5 mm.

In some embodiments, a sum of widths of the half-etched portions of each unit element and its adjacent unit element is greater than or equal to approximately 0.5 mm.

According to another aspect of the present disclosure, there is provided an open mask assembly, comprising:

a base plate having a protruding film layer; and

the open mask according to any one of the aforementioned embodiments, wherein an orthographic projection of the protruding film layer onto the base plate is located in an orthographic projection of the half-etched portion of the open mask onto the base plate.

According to yet another aspect of the present disclosure, there is provided an evaporation method using the open mask according to any one of the aforementioned embodiments, the evaporation method comprising:

providing the open mask;

disposing a base plate having a protruding film layer on the open mask, such that an orthographic projection of the protruding film layer onto the base plate is located in an orthographic projection of the half-etched portion of the open mask onto the base plate; and

performing an evaporation within the open area of the open mask by a nozzle.

In some embodiments, the nozzle is configured so that its maximum spraying angle is approximately 53 degrees with respect to a horizontal plane parallel to the open mask.

### BRIEF DESCRIPTION OF THE DRAWINGS

FIG. 1 is a schematic view showing a partial structure of an open mask in related art;

FIG. 2 is a schematic view showing a partial structure of an open mask according to an embodiment of the present disclosure; and

FIG. 3 is a top view showing a partial structure of the open mask according to the embodiment of the present disclosure.

### DETAILED DESCRIPTION OF THE EMBODIMENTS

In order to make the objects, technical solutions, and advantages of the present disclosure more clear, embodiments of the present disclosure will be described in detail below with reference to the accompanying drawings. It should be noted that many specific details are set forth in the following description in order to fully understand the present disclosure. However, the present disclosure can also be implemented in other ways than described herein. Therefore, the protection scope of the present disclosure is not limited by the specific embodiments disclosed below.

FIG. 1 shows a schematic view of a partial structure of an open mask in related art. As shown in FIG. 1, the open mask includes an open area and a non-open area that defines the open area. The non-open area includes a material reserved portion and a half-etched portion. The half-etched portion is formed directly around each open area. A glass base plate having a protruding film layer is provided on the surface of the open mask where the half-etched portion is formed. The inventors of the present disclosure have found that such a design, when evaporation spraying is performed by nozzles, will make the external shadow A larger and thus affect product performance.

An embodiment of the present disclosure provides an open mask. The open mask includes: a plurality of unit elements arranged in an array, each unit element includes an open area and a non-open area, and the non-open area includes a half-etched portion and a material reserved portion, wherein: in at least one unit element of the plurality of unit elements, the material reserved portion is located around the open area of the at least one unit element, and the half-etched portion is isolated from the open area by the material reserved portion. An open mask assembly including the aforementioned open mask and an evaporation method using the aforementioned open mask are also provided.

Please refer to FIG. 2 and FIG. 3. FIG. 2 is a schematic view showing a partial structure of an open mask according to an embodiment of the present disclosure; and FIG. 3 is a top view showing a partial structure of the open mask according to the embodiment of the present disclosure. The open mask according to the embodiment of the present disclosure includes a plurality of unit elements arranged in an array (in the illustrated embodiment, two adjacent unit elements 100a and 100b are taken as examples), each unit element 100a or 100b includes an open area 301 and a non-open area 201, 202. The non-open area includes a half-etched portion 201 and a material reserved portion 202. In at least one unit element (such as two adjacent unit elements 100a and 100b in the illustrated embodiment), the material reserved portion 202 is located around the open area 301 of the unit element 100a or 100b, and the half-etched portion 201 is isolated from the open area 301 by the material reserved portion 202.

It should be noted that although only two adjacent unit elements 100a and 100b are shown in the embodiment shown in FIGS. 2 and 3, the open mask according to the embodiment of the present disclosure is formed by arranging a plurality of unit elements each having the aforementioned structure in an array manner. For example, FIG. 3 exemplarily shows two adjacent unit elements 100a and 100b, each unit element 100a or 100b has the open area 301, and each open area 301 is surrounded by the material reserved portion 202, and the material reserved portion 202 is in turn surrounded by the half-etched portion 201.

In the related art, when an open mask is used for evaporation, evaporation material is required to be sprayed with nozzles. Because the liquid is sprayed at a certain angle during nozzle spraying, external shadows appear. In the embodiment of the present disclosure, the material reserved portion at the periphery of the open area can be used to block external shadows. Under the same evaporation conditions (such as temperature and angle), the B value area is necessarily smaller than the A value area. For example, in FIG. 2, width of the external shadow is B, and it can be seen that it is much smaller than width A of the external shadow in FIG. 1, the A value being approximately 200μm.

For the open mask shown in FIG. 1, it is found in the actual evaporation results that, besides the theoretically calculated A value area as the external shadow, there are still some metal particles in the area beyond the A value area on the base plate. For this phenomenon, the general reasoning is that because the half-etched portion is on contact surface of the base plate, in addition to the metal particles attached to the base plate at a fixed angle, there is still a small part of the metal particles “floating” to areas beyond A value area due to free movement, the half-etched part of the design shown in FIG. 1 just provides space for theirs “floating”.

For the open mask shown in FIG. 2, the material reserved portion of certain width around the open area is used to block the “floating” phenomenon of metal particles. At the same time, the B value area of the external shadow is also much smaller than the A value area according to calculations based on the angles. In the open mask according to the embodiment of the present disclosure, since the material reserved portion is located around the open area, during the evaporation spraying, the evaporation material cannot enter the half-etched portion through the material reserved portion, so the coverage area where vapor deposition material entering the open mask is smaller, thereby reducing external shadow effect of the open mask.

In an exemplary embodiment, as shown in FIG. 2, in a non-open area, between the material reserved portions 202 of the two adjacent unit elements 100a and 100b, all are the half-etched portion 201. That is, between the material reserved portions 202 of the two adjacent unit elements 100a and 100b, the half-etched portion 201 of one unit element 100a and the half-etched portion 201 of another unit element 100b adjacent to the unit element 100a adjoin each other.

The number of the material reserved portions 202 is as small as possible, which can reduce the technological difficulty. Meanwhile, the number of the material reserved portions 202 is as small as possible and the width of the material reserved portion 202 is as small as possible, which can make the weight of the open mask smaller, thereby effectively improving the sagging amount of the open mask when it is tensioned, that is, the flatness is improved. Increasing the flatness can further ensure the closeness between the open mask and base plate in the evaporation process, and further ensure that the shadow on the entire surface is reduced.

Generally, for the open mask shown in FIG. 1, its flatness is approximately 350μm. For the open mask shown in FIG. 2, its flatness can reach approximately 250μm.

Generally, the overall thickness of the open mask is approximately 145-155μm, and commonly the overall thickness of the open mask is approximately 150μm. The thickness of the material reserved portion 202 is the same as the overall thickness of the open mask, which is also approximately 145-155μm. For example, H1 marked in FIG. 2 is the thickness of the material reserved portion 202.

Provision of the half-etched portion 201 is mainly to avoid the protruding film layer 204. Generally, as long as the half-etched portion 201 is etched away approximately 10μm, the purpose of avoiding the protruding film layer 204 can be achieved. Therefore, a difference between the thickness of the material reserved portion 202 and a thickness of the half-etched portion 201 of the open mask is at least approximately 10μm. When the thickness of the material reserved portion 202 is approximately 150μm, the thickness of the half-etched portion 201 of the open mask is less than approximately 140μm, and H2 marked in FIG. 2 is the thickness of the half-etched portion 201.

Generally speaking, for the convenience of manufacturing technology, the thickness of the half-etched portion of the open mask is generally approximately 70-80μm.

The smaller the width of the material reserved portion 202 of the open mask, the lighter the weight of the open mask, which is more helpful to improve the flatness of the entire surface of the open mask. In order to reduce the technological difficulty of manufacturing the open mask, in general, the width of the material reserved portion 202 of the open mask is greater than or equal to approximately 0.5 mm. For example, D1 marked in FIG. 2 is the width of the material reserved portion 202.

Generally, a sum of widths of the half-etched portions of each unit element and its adjacent unit element is greater than or equal to approximately 0.5 mm. For example, D2 marked in FIG. 2 is the width of the half-etched portion 201.

In accordance with the embodiments of the present disclosure, there is further provided an open mask assembly. As shown in FIG. 2, the open mask assembly includes: a base plate 203 having a protruding film layer 204; and the open mask as described above. As shown in FIG. 2, an orthographic projection of the protruding film layer 204 onto the base plate 203 is located in an orthographic projection of the half-etched portion 201 of the open mask onto the base plate 203. In this way, the half-etched portion is used to avoid the protruding film layer on the base plate, and to avoid squeezing or rubbing between the open mask and the protruding film layer, causing damage to the film layer structure and granulation.

For the two designs shown in FIG. 1 and FIG. 2, the open mask is half-etched at the position corresponding to the protruding film layer on the base plate. The protruding film layer on the base plate is usually used to form a barrier when packaging OLED devices, so its integrity should be guaranteed. The half-etching of the corresponding area can effectively avoid squeezing or rubbing of the protruding film layer and the open mask to cause the barrier to be damaged.

In practical applications, in the non-open area, in addition to the material reserved portion around the open area, there may be other material reserved portions between the material reserved portions of two adjacent unit elements, as long as half-etching is performed on the open mask at the protruding film layer to form the half-etched portion.

In accordance with the embodiments of the present disclosure, there is further provided an evaporation method using the aforementioned open mask. The evaporation method includes: providing the aforementioned open mask; disposing the base plate having the protruding film layer on the open mask, such that an orthographic projection of the protruding film layer onto the base plate is located in an orthographic projection of the half-etched portion of the open mask onto the base plate; and performing an evaporation on the open area of the open mask by a nozzle. In an exemplary embodiment, as shown in FIG. 2, the nozzle 400 is configured so that a maximum spraying angle is approximately 53 degrees with respect to a horizontal plane parallel to the open mask. In the evaporation method according to the embodiment of the present disclosure, since the material reserved portion of the open mask is located around the open area, when the evaporation spraying is performed, the evaporation material cannot enter the half-etched portion through the material reserved portion, so the coverage area where vapor deposition material entering the open mask is smaller, thereby reducing external shadow effect of the open mask.

The above description is only exemplary embodiments of the present disclosure. Those skilled in the art should understand that the protection scope of the present disclosure is not limited to the technical solution consisted of the specific combination of the above-mentioned technical features, but also covers other technical solutions formed by arbitrarily combining the above-mentioned technical features or their equivalents without departing from the inventive concept of the present disclosure, for example, a technical solution formed by replacing the above-mentioned features with technical features with similar functions described in the present disclosure (but not limited thereto).

1. An open mask comprising:
a plurality of unit elements arranged in an array, each unit element comprising an open area and a non-open area, the non-open area comprising a half-etched portion and a material reserved portion, wherein:
in at least one unit element of the plurality of unit elements, the material reserved portion is located around the open area of the at least one unit element, and the half-etched portion is isolated from the open area by the material reserved portion.

2. The open mask of claim 1, wherein each unit element and its adjacent unit element have their half-etched portions adjoining each other.

3. The open mask of claim 1, wherein a thickness of the material reserved portion is approximately 145-155μm.

4. The open mask of claim 3, wherein a difference between the thickness of the material reserved portion and a thickness of the half-etched portion is at least approximately 10μm.

5. The open mask of claim 3, wherein a thickness of the half-etched portion is approximately 70-80μm.

6. The open mask of claim 1, wherein a width of the material reserved portion is greater than or equal to approximately 0.5 mm.

7. The open mask of claim 2, wherein a sum of widths of the half-etched portions of each unit element and its adjacent unit element is greater than or equal to approximately 0.5 mm.

8. An open mask assembly, comprising:
a base plate having a protruding film layer; and
the open mask according to claim 1, wherein an orthographic projection of the protruding film layer onto the base plate is located in an orthographic projection of the half-etched portion of the open mask onto the base plate.

9. An evaporation method using the open mask according to claim 1, the evaporation method comprising:
providing the open mask;
disposing a base plate having a protruding film layer on the open mask, such that an orthographic projection of the protruding film layer onto the base plate is located in an orthographic projection of the half-etched portion of the open mask onto the base plate; and
performing an evaporation within the open area of the open mask by a nozzle.

10. The evaporation method of claim 9, wherein the nozzle is configured so that its maximum spraying angle is approximately 53 degrees with respect to a horizontal plane parallel to the open mask.

11. The open mask assembly of claim 8, wherein in the open mask, each unit element and its adjacent unit element have their half-etched portions adjoining each other.

12. The open mask assembly of claim 8, wherein in the open mask, a thickness of the material reserved portion is approximately 145-155μm, and a width of the material reserved portion is greater than or equal to approximately 0.5 mm.

13. The open mask assembly of claim 12, wherein in the open mask, a difference between the thickness of the material reserved portion and a thickness of the half-etched portion is at least approximately 10μm.

14. The open mask assembly of claim 12, wherein in the open mask, a thickness of the half-etched portion is approximately 70-80μm.

15. The open mask assembly of claim 11, wherein in the open mask, a sum of widths of the half-etched portions of each unit element and its adjacent unit element is greater than or equal to approximately 0.5 mm.

16. The evaporation method of claim 9, wherein in the open mask, each unit element and its adjacent unit element have their half-etched portions adjoining each other.

17. The evaporation method of claim 9, wherein in the open mask, a thickness of the material reserved portion is approximately 145-155μm, and a width of the material reserved portion is greater than or equal to approximately 0.5 mm.

18. The evaporation method of claim 17, wherein in the open mask, a difference between the thickness of the material reserved portion and a thickness of the half-etched portion is at least approximately 10μm.

19. The evaporation method of claim 17, wherein in the open mask, a thickness of the half-etched portion is approximately 70-80μm.

20. The evaporation method of claim 16, wherein in the open mask, a sum of widths of the half-etched portions of each unit element and its adjacent unit element is greater than or equal to approximately 0.5 mm.
